(19) United States
(12) Patent Application Publication
(10) Pub. No.: US 2013/0335117 A1
(43) Pub. Date: Dec. 19, 2013

(54) PRE-DRIVER AND DIFFERENTIAL SIGNAL TRANSMITTER USING THE SAME

(71) Applicant: NOVATEK MICROELECTRONICS CORP., Hsinchu (TW)

(72) Inventor: Hsiang-Chi Li, Hsinchu City (TW)

(73) Assignee: NOVATEK MICROELECTRONICS CORP., Hsinchu (TW)

(21) Appl. No.: 13/666,983

(22) Filed: Nov. 2, 2012

(30) Foreign Application Priority Data
Jun. 13, 2012 (TW) 101121155

(51) Int. Cl. H03K 19/0175

(52) U.S. Cl. 326/82

(57) ABSTRACT

A pre-driver and a differential signal transmitter using the same are provided. The pre-driver includes a latch circuit and a driver buffer. The latch circuit includes latch units, first inverters, and second inverters. The latch units are coupled in series between a pair of differential input terminals and a pair of differential latch terminals, receive a pair of differential input signals through the pair of differential input terminals, and latch the pair of differential input signals according to a clock signal to provide a pair of differential latch signals through the pair of differential latch terminals. The first and second inverters are respectively coupled in series between the pair of differential latch terminals and a pair of differential output terminals. The driver buffer is coupled to the pair of differential output terminals to receive a pair of differential output signals, and accordingly provides a pair of differential pre-driver output signals.

### CROSS-REFERENCE TO RELATED APPLICATION

This application claims the priority benefit of Taiwan application serial no. 101121155, filed on Jun. 13, 2012. the entirety of the above-mentioned patent application is hereby incorporated by reference herein and made a part of this specification.

### BACKGROUND

1. Technical Field

The invention relates to a signal transmission device. Particularly, the invention relates to a pre-driver of differential signals and a differential signal transmitter using the same.

2. Related Art

Signal (or data) transmission between or in internal of electronic devices is gradually developed towards a trend of high-speed transmission. In order to transmit signals in a high speed, most of high-speed input/output systems use differential signals to transmit data, so as to resist noise interference during the process of high-speed signal transmission, and simultaneously reduce interference on other circuit caused by the data transmission.

Generally, a data signal is converted into differential signals through a plurality of steps (for example, sampling, signal conversion, driving capability amplification and voltage cross point adjustment, etc.), and these steps are generally executed by a plurality of circuits, respectively, i.e. a conventional differential signal transmitter has a plurality of circuits. Moreover, as the semiconductor technology is quickly developed, the differential signal transmitter is integrated into a chip to reduce a size of the electronic device. Moreover, manufacturing cost of the chip is correlated to a chip area thereof, and the cost of the electronic device influences a market competitiveness of the electronic device. Therefore, how to simplify the differential signal transmitter becomes an important issue in design of the differential signal transmitter.

### SUMMARY

A pre-driver and a differential signal transmitter using the same are disclosed, in which a circuit design of the pre-driver is simplified to reduce manufacturing cost and power consumption of the pre-driver and the differential signal transmitter using the same.

In an aspect, a pre-driver including a latch circuit and a driver buffer is provided. The latch circuit includes one or more latch units, one or more first inverters, and one or more second inverters. The one or more latch units are coupled in series between a pair of differential input terminals and a pair of differential latch terminals, receive a pair of differential input signals through the pair of differential input terminals, and latch the pair of differential input signals according to a clock signal to provide a pair of differential latch signals through the pair of differential latch terminals. The one or more first inverters are coupled in series between a first terminal of the pair of differential latch terminals and a first terminal of a pair of differential output terminals. The one or more second inverters are coupled in series between a second terminal of the pair of differential latch terminals and a second terminal of the pair of differential output terminals. The driver buffer has a pair of buffer input terminals coupled to the pair of differential output terminals of the latch circuit to receive a pair of differential output signals, and accordingly provides a pair of differential pre-driver output signals through a pair of buffer output terminals according to the pair of differential output signals.

In an embodiment of the invention, the one or more first inverters and the one or more second inverters are used to adjust a level of a cross point of the pair of differential latch signals to produce the pair of differential output signals.

In an embodiment of the invention, each of the latch units has a clock input terminal, a pair of differential data input terminals and a pair of differential data output terminals. The pair of differential data input terminals of a first one of the one or more latch units serve as the pair of differential input terminals; the pair of differential data input terminals of each of the one or more latch units besides the first latch unit are coupled to the differential data output terminals of a previous latch unit; the pair of differential data output terminals of a last one of the one or more latch units serve as the pair of differential latch terminals; and the clock input terminal of each of the one or more latch units receives one of the clock signal and an inverted signal of the clock signal, the each of the one or more latch units latches a pair of differential signals received by the pair of differential data input terminals according to the clock signal or the inverted signal, and outputs the latched pair of differential signals through the pair of differential data output terminals.

In an embodiment of the invention, each of the one or more latch units includes a current source, a differential pair and a latch block. The current source receives the clock signal or the inverted signal of the clock signal through the clock input terminal, and provides a current according to the clock signal or the inverted signal. The differential pair is coupled between the current source and the pair of differential data output terminals, and is coupled to the pair of differential signals through the pair of differential data input terminals. The latch block is coupled between a first terminal and a second terminal of the pair of differential data output terminals, and latches a voltage level of the pair of differential data output terminals to produce the latched pair of differential signals.

In an embodiment of the invention, the current source includes a transistor, where a first terminal of the transistor serves as the clock input terminal, a second terminal thereof is coupled to a reference voltage, and a third terminal thereof is coupled to the differential pair.

In an embodiment of the invention, the differential pair includes a first transistor and a second transistor. A first terminal of the first transistor serves as a first terminal of the pair of differential data input terminals, a second terminal thereof is coupled to the current source, and a third terminal thereof is coupled to the first terminal of the pair of differential data output terminals. A first terminal of the second transistor serves as a second terminal of the pair of differential data input terminals, a second terminal thereof is coupled to the current source, and a third terminal thereof is coupled to the second terminal of the pair of differential data output terminals.

In an embodiment of the invention, the latch block includes a first inverter and a second inverter. An input terminal of the first inverter is coupled to the first terminal of the pair of differential data output terminals, and an output terminal thereof is coupled to the second terminal of the pair of differential data output terminals. An input terminal of the second inverter is coupled to the second terminal of the pair of differential data output terminals, and an output terminal thereof is coupled to the first terminal of the pair of differential data output terminals.

In an embodiment of the invention, the latch block includes a first NAND gate and a second NAND gate. A first input terminal of the first NAND gate is coupled to the first terminal of the pair of differential data output terminals, a second input terminal thereof receives one of a system voltage and a reset signal, and an output terminal thereof is coupled to the second terminal of the pair of differential data output terminals. A first input terminal of the second NAND gate is coupled to the second terminal of the pair of differential data output terminals, a second input terminal thereof receives another one of the system voltage and the reset signal, and an output terminal thereof is coupled to the first terminal of the pair of differential data output terminals.

In an embodiment of the invention, the first latch circuit includes a first NOR gate and a second NOR gate. A first input terminal of the first NOR gate is coupled to the first terminal of the pair of differential data output terminals, a second input terminal thereof receives one of a ground voltage and a reset signal, and an output terminal thereof is coupled to the second terminal of the pair of differential data output terminals. A first input terminal of the second NOR gate is coupled to the second terminal of the pair of differential data output terminals, a second input terminal thereof receives another one of the ground voltage and the reset signal, and an output terminal thereof is coupled to the first terminal of the pair of differential data output terminals.

In an embodiment of the invention, the pre-driver further includes an inverter, which is configured to invert a data signal, where the inverted data signal and the data signal serve as the pair of differential input signals.

In another aspect, a differential signal transmitter is also provided, including the aforementioned pre-driver and a current mode driver. The current mode driver is coupled to the pre-driver.

According to the above descriptions, in the pre-driver and the differential signal transmitter using the same, a circuit design of the pre-driver can be simplified to reduce a chip area of the pre-driver and the differential signal transmitter using the same integrated in a chip, reduce a signal latency of the pre-driver and the differential signal transmitter using the same, reduce jitter of the differential signals and reduce power consumption of the pre-driver and the differential signal transmitter using the same. Moreover, conversion of the differential signals can not be influenced by the manufacturing process, voltage and temperature.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a system schematic diagram of a differential signal transmitter according to an embodiment of the invention.

FIG. 2A is a system schematic diagram of a pre-driver according to an embodiment of the invention.

FIG. 2B is a system schematic diagram of a pre-driver according to another embodiment of the invention.

FIG. 2C is a system schematic diagram of a pre-driver according to still another embodiment of the invention.

FIG. 2D is a system schematic diagram of a pre-driver according to yet another embodiment of the invention.

FIG. 3A is a circuit schematic diagram of a latch unit according to an embodiment of the invention.

FIG. 3B is a circuit schematic diagram of a latch unit according to another embodiment of the invention.

FIG. 3C is a circuit schematic diagram of a latch unit according to still another embodiment of the invention.

FIG. 4A is a circuit schematic diagram of a current mode driver according to an embodiment of the invention.

FIG. 4B is a circuit schematic diagram of a current mode driver according to another embodiment of the invention.

### DETAILED DESCRIPTION OF DISCLOSED EMBODIMENTS

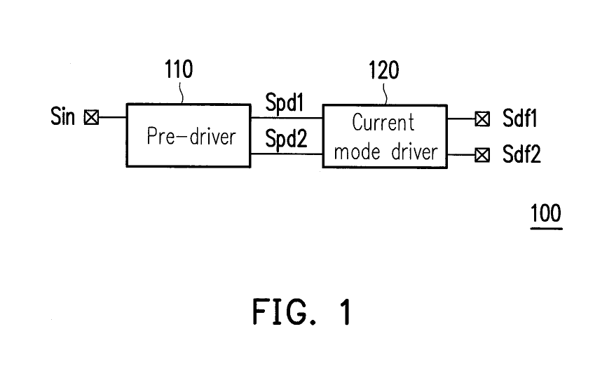

FIG. 1 is a system schematic diagram of a differential signal transmitter according to an embodiment of the invention. Referring to FIG. 1, in the present embodiment, the differential signal transmitter 100 includes a pre-driver 110 and a current mode driver 120. The pre-driver 110 receives an input signal Sin, and generates a pair of differential pre-driver output signals Spd1 and Spd2 according to the input signal Sin. The current mode driver 120 is coupled to the pre-driver 110, and generates a pair of driving differential signals Sdf1 and Sdf2 according to the pair of differential pre-driver output signals Spd1 and Spd2.

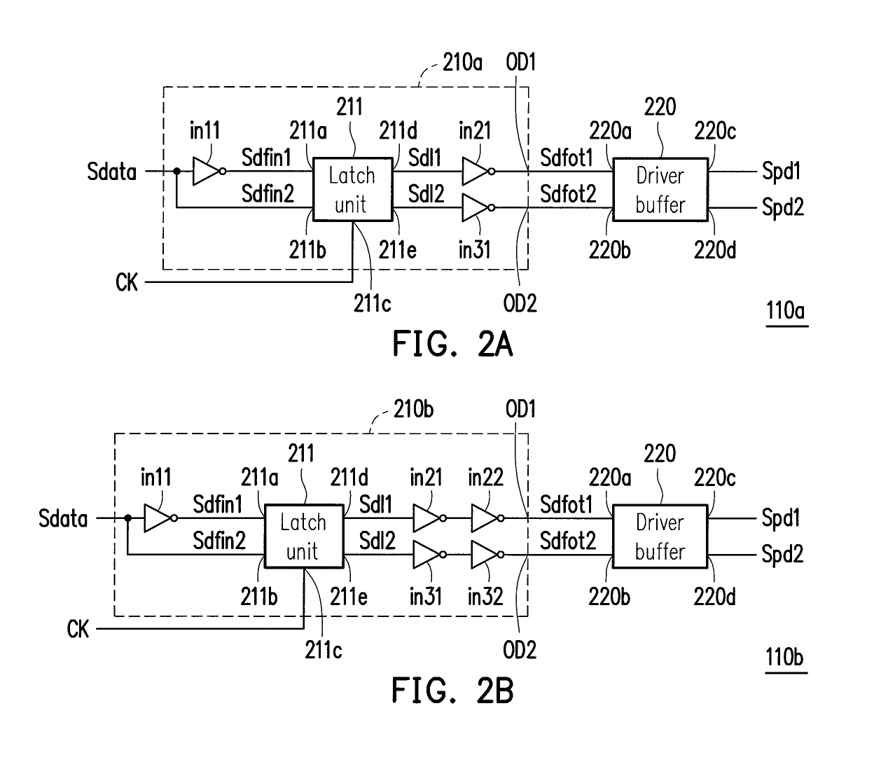

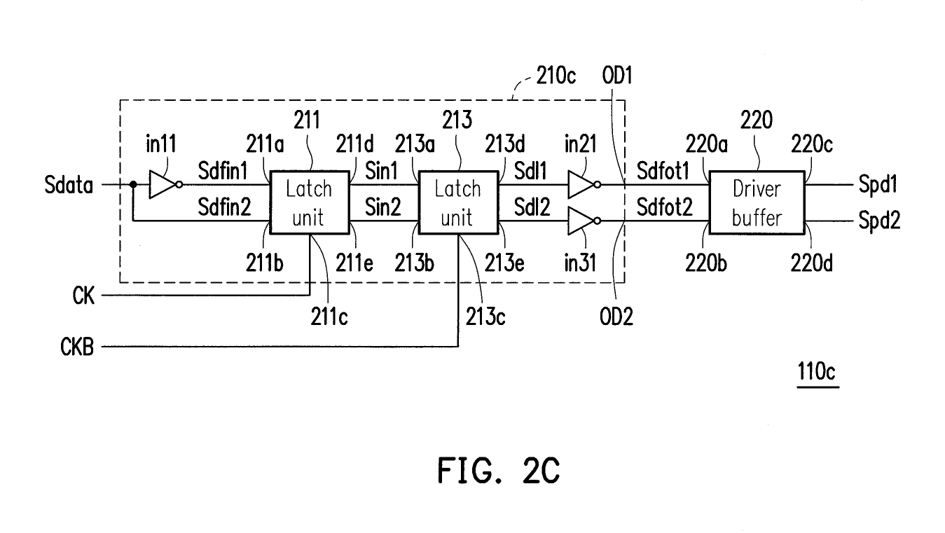

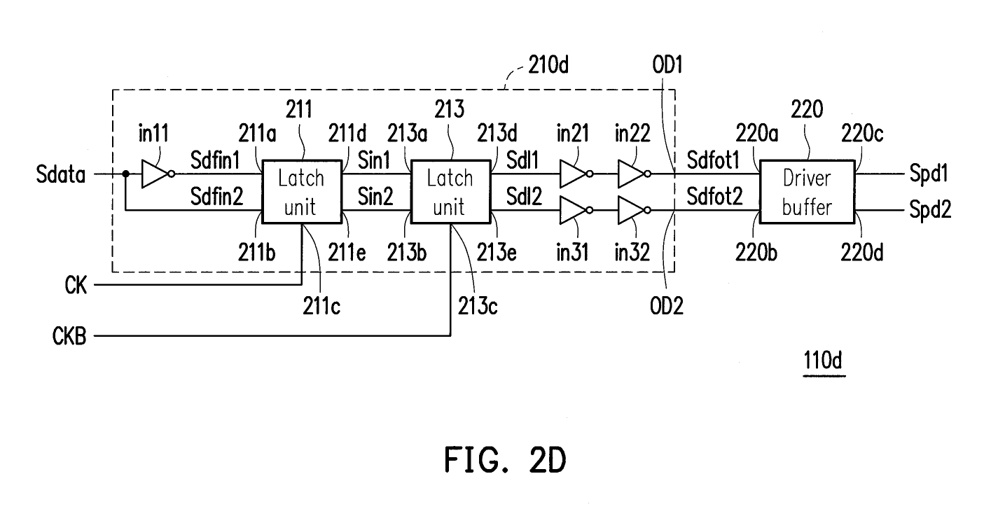

FIG. 2A is a system schematic diagram of a pre-driver according to an embodiment of the invention, which can be applied but not limited to the differential signal transmitter 100 of FIG. 1. Referring to FIG. 1 and FIG. 2A, in the present embodiment, the input signal Sin is, for example, a data signal Sdata, and the pre-driver 110a includes a latch circuit 210a and a driver buffer 220. The latch circuit 210a receives the data signal Sdata, and provides a pair of differential output signals Sdfot1 and Sdfot2 through a pair of differential output terminals OD1 and OD2 according to the data signal Sdata. The driver buffer 220 is coupled to the latch circuit 210a, and produces the differential pre-driver output signals Spd1 and Spd2 according to the differential output signals Sdfot1 and Sdfot2.

In the present embodiment, the latch circuit 210a includes inverters in11, in21 and in31 and a latch unit 211. An input terminal of the inverter in11 receives the data signal Sdata, and inverts the data signal Sdata for outputting, wherein the inverted data signal Sdata serves as a differential input signal Sdfin1, and the data signal Sdata serves as a differential input signal Sdfin2.

The latch unit 211 has a pair of differential data input terminals 211a and 211b, a clock input terminal 211c and a pair of differential data output terminals 211d and 211e, wherein the differential data input terminals 211a and 211b are respectively coupled to the output terminal and the input terminal of the inverter in11. The latch unit 211 latches a pair of differential signals received through the differential data input terminals 211a and 211b according to a clock signal CK received through the clock input terminal 211c, and outputs the latched differential signals through the differential data output terminals 211d and 211e. In other words, the latch unit 211 latches the pair of differential input signals Sdfin1 and Sdfin2 received through the differential data input terminals 211a and 211b according to the clock signal CK, and provides a pair of differential latch signals Sdl1 and Sdl2 through the differential data output terminals 211d and 211e after latching the differential input signals Sdfin1 and Sdfin2.

In the present embodiment, the differential data input terminals 211a and 211b are used to receive the differential input signals Sdfin1 and Sdfin2, i.e. the differential data input terminals 211a and 211b can be regarded as a pair of differential input terminals. The differential data output terminals 211d and 211e are used to provide the differential latch signals Sdl1 and Sdl2, i.e. the differential data output terminals 211d and 211e can be regarded as a pair of differential latch terminals. According to the above descriptions, the latch unit 211 can be regarded as being coupled between the differential input terminals (there are the differential data input terminals 211a and 211b, for example) and the differential latch terminals (there are the differential data output terminals 211d and 211e, for example).

The inverter in21 (corresponding to a first inverter of the latch circuit) is coupled between the differential data output terminal 211d (corresponding to a first terminal of the differential latch terminals) and the differential output terminal OD 1 (corresponding to a first terminal of the pair of differential output terminals). The inverter in31 (corresponding to a second inverter of the latch circuit) is coupled between the differential data output terminal 211e (corresponding to a second terminal of the differential latch terminals) and the differential output terminal OD2 (corresponding to a second terminal of the pair of differential output terminals). The inverter in21 inverts the differential latch signal Sdl1 to generate the differential output signal Sdfot1, and the inverter in31 inverts the differential latch signal Sdl2 to generate the differential output signal Sdfot2.

Therefore, the inverters in21 and in31 can adjust a level of a cross point of the differential latch signals Sdl1 and Sdl2 to produce the differential output signals Sdfot1 and Sdfot2. For example, when the level of the cross point of the differential latch signals Sdl1 and Sdl2 is a low level (i.e. lower than an average level of the differential latch signals Sdl1 and Sdl2), a level of a cross point of the differential output signals Sdfot1 and Sdfot2 is adjusted to a high level (i.e. higher than an average level of the differential output signals Sdfot1 and Sdfot2). When the level of the cross point of the differential latch signals Sdl1 and Sdl2 is a high level (i.e. higher than the average level of the differential latch signals Sdl1 and Sdl2), the level of the cross point of the differential output signals Sdfot1 and Sdfot2 is adjusted to a low level (i.e. lower than the average level of the differential output signals Sdfot1 and Sdfot2).

The driver buffer 220 has buffer input terminals 220a and 220b and buffer output terminals 220c and 220d, where the buffer input terminals 220a and 220b are coupled to the differential output terminals OD 1 and OD2 of the latch circuit 210a to receive the differential output signals Sdfot1 and Sdfot2 and provide the differential pre-driver output signals Spd1 and Spd2 through the buffer output terminals 220c and 220d according to the differential output signals Sdfot1 and Sdfot2.

In an embodiment of the invention, when the input signal Sin is the differential input signals Sdfin1 and Sdfin2, the inverter in11 can be omitted, i.e. the pre-driver 210a is composed of the inverters in21 and in31 and the latch unit 211.

FIG. 2B is a system schematic diagram of a pre-driver according to another embodiment of the invention. Referring to FIG. 2A and FIG. 2B, a difference between the pre-driver 110a and the pre-driver 110b lies in a latch circuit 210b which further includes inverters in22 and in32. In the present embodiment, the inverters in21 and in22 (corresponding to the first inverters of the latch circuit) are coupled in series between the differential data output terminal 211d (corresponding to the first terminal of the differential latch terminals) and the differential output terminal OD1 (corresponding to the first terminal of the pair of differential output terminals). The inverters in31 and in32 (corresponding to the second inverters of the latch circuit) are coupled in series between the differential data output terminal 211e (corresponding to the second terminal of the differential latch terminals) and the differential output terminal OD2 (corresponding to the second terminal of the pair of differential output terminals).

The inverters in21 and in22 double invert the differential latch signal Sdl1 to produce the differential output signal Sdfot1, and the inverters in31 and in32 double invert the differential latch signal Sdl2 to produce the differential output signal Sdfot2, i.e. the inverters in21, in22, in31 and in32 adjust a level of a cross point of the differential latch signals Sdl1 and Sdl2 to produce the differential output signals Sdfot1 and Sdfot2. For example, when the level of the cross point of the differential latch signals Sdl1 and Sdl2 is a low level (i.e. lower than an average level of the differential latch signals Sdl1 and Sdl2), the level of the cross point of the differential output signals Sdfot1 and Sdfot2 is adjusted to a low level (i.e. lower than an average level of the differential output signals Sdfot1 and Sdfot2). When the level of the cross point of the differential latch signals Sdl1 and Sdl2 is a high level (i.e. higher than the average level of the differential latch signals Sdl1 and Sdl2), the level of the cross point of the differential output signals Sdfot1 and Sdfot2 is adjusted to a higher level (i.e. higher than the average level of the differential output signals Sdfot1 and Sdfot2).

FIG. 2C is a system schematic diagram of a pre-driver according to still another embodiment of the invention. Referring to FIG. 2A and FIG. 2C, a difference between the pre-driver 110a and the pre-driver 110c lies in a latch circuit 210c. The latch circuit 210c further includes a latch unit 213. The latch unit 213 has a pair of differential data input terminals 213a and 213b, a clock input terminal 213c and a pair of differential data output terminals 213d and 213e, where the differential data input terminals 213a and 213b are respectively coupled to the differential data output terminals 211d and 211e of the latch unit 211, and the differential data output terminals 213d and 213e are respectively coupled to the input terminals of the inverters in21 and in31. Similarly, the latch unit 213 latches a pair of differential signals received through the differential data input terminals 213a and 213b according to an inverted signal CKB of the clock signal CK received through the clock input terminal 213c, and outputs the latched differential signals through the differential data output terminals 213d and 213e.

In other words, the latch unit 211 (corresponding to a first latch unit) latches the pair of differential input signals Sdfin1 and Sdfin2 received through the differential data input terminals 211a and 211b according to the clock signal CK, and provides a pair of differential latch signals Sin1 and Sin2 through the differential data output terminals 211d and 211e after latching the differential input signals Sdfin1 and Sdfin2. The latch unit 213 (corresponding to a last latch unit) latches the differential signals Sin1 and Sin2 received through the differential data input terminals 213a and 213b according to the inverted signal CKB, and provides the pair of differential latch signals Sdl1 and Sdl2 through the differential data output terminals 213d and 213e after latching the differential signals Sin1 and Sin2.

In the present embodiment, the differential data input terminals 211a and 211b are used to receive the differential input signals Sdfin1 and Sdfin2, i.e. the differential data input terminals 211a and 211b can be regarded as a pair of differential input terminals. The differential data output terminals 213d and 213e are used to provide the differential latch signals Sdl1 and Sdl2, i.e. the differential data output terminals 213d and 213e can be regarded as a pair of differential latch terminals. According to the above descriptions, the latch units 211 and 213 can be regarded to be coupled in series between the differential input terminals (there are the differential data input terminals 211a and 211b, for example) and the differential latch terminals (there are the differential data output terminals 213d and 213e, for example).

FIG. 2D is a system schematic diagram of a pre-driver according to yet another embodiment of the invention. Referring to FIG. 2A and FIG. 2D, a difference between the pre-driver 110a and the pre-driver 110d lies in a latch circuit 210d which further includes a latch unit 213 and inverters in22 and in32. In the present embodiment, related descriptions of the embodiment of FIG. 2B can be referred to for descriptions of the inverters in22 and in32, and related descriptions of the embodiment of FIG. 2C can be referred to for descriptions of the latch unit 213, which are not repeated.

It should be noticed that according to the embodiments of FIGS. 2A-2D, in other embodiments of the invention, the number of the latch units (for example, 211 and 213) can be one or more (which can be more than two), and the latch units cab be coupled in series between the differential input terminals (for example, the differential data input terminals 211a and 211b) and the differential latch terminals (for example, the differential data output terminals 213d and 213e), and the clock signals received by the clock input terminals can be CK and CKB alternately ( . . . CK, CKB, . . . , by turns), wherein a coupling method of the latch units (for example, 211 and 213) can be deduced according to the embodiment of FIG. 2C. Moreover, when the latch circuit (for example, 210a-210d) is composed of two or more latch units (for example, 211 and 213) coupled in series, the latch circuit (for example, 210a-210d) can form a flip-flop.

On the other hand, the number of the inverters (for example, in21 and in22) coupled in series between the first terminals of the differential latch terminals (for example, the differential data output terminals 211d and 213d) and the differential output terminal OD1 and the number of the inverters (for example, in31 and in32) coupled in series between the second terminals of the differential latch terminals (for example, the differential data output terminals 211e and 213e) and the differential output terminal OD2 can be one or more (which can be more than two), and such number can be determined according to the level of the cross point of the differential latch signals Sdl1 and Sdl2 and the expected level of the cross point of the differential output signals Sdfot1 and Sdfot2, which is not limited by the invention.

According to the embodiments of FIG. 2A-FIG. 2D, the pre-drivers 110a-110d can provide the differential pre-driver output signals Spd1 and Spd2 to the current mode driver under simple structures. In detail, in case that the input signal is a single-end signal, the latch circuits 210a-210d can convert the single-end signal into differential signals. Moreover, the latch circuits 210a-210d can further adjust the cross-point of the differential pre-driver output signals Spd1 and Spd2 entering the current mode driver. On the other hand, the driver buffer 220 in the pre-drivers 110a-110d may increase a driving capability of the differential pre-driver output signals Spd1 and Spd2.

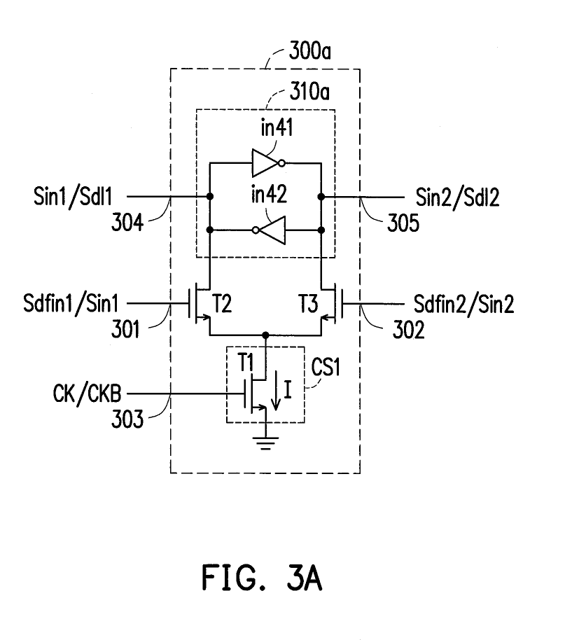

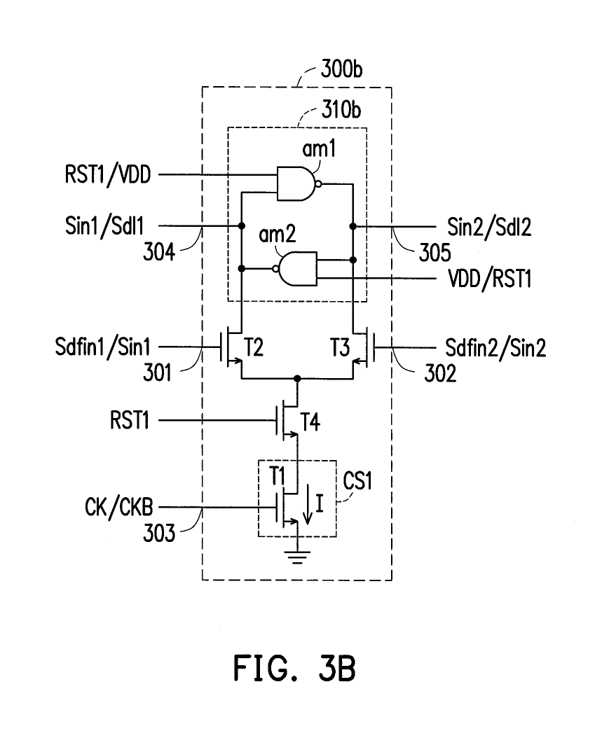

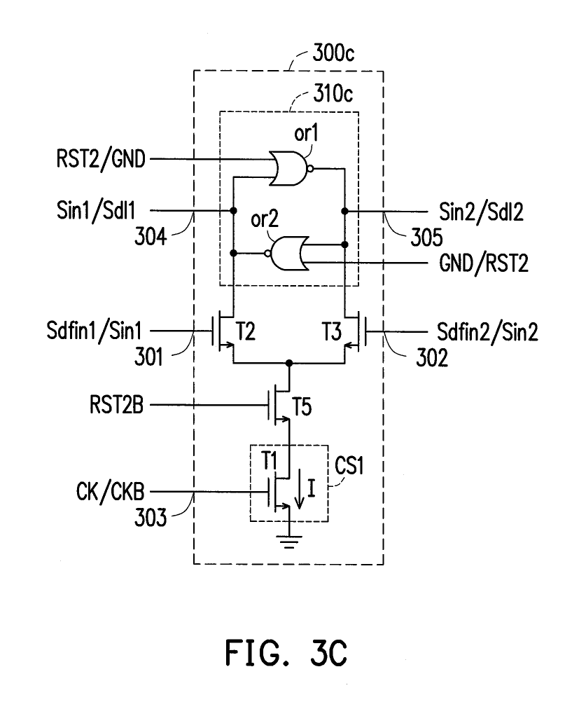

FIG. 3A is a circuit schematic diagram of a latch unit according to an embodiment of the invention, which can be applied but not limited to any one of the pre-drivers 110a-110d shown in FIGS. 2A-2D. Referring to FIG. 3A, in the present embodiment, the latch unit 300a includes a current source CS1, a differential pair and a latch block 310a, and the latch unit 300a has differential data input terminals 301 and 302, a clock input terminal 303 and differential data output terminals 304 and 305. The current source CS1 is, for example, implemented by a transistor T1, the differential pair is for example, implemented by transistors T2 and T3, and the latch block 310a is, for example, implemented by inverters in41 and in42.

A gate (corresponding to a first terminal) of the transistor T1 receives the clock signal CK or the inverted signal CKB of the clock signal CK through the clock input terminal 303, a source (corresponding to a second terminal) of the transistor T1 is coupled to a reference voltage (for example, a ground voltage), and a drain (corresponding to a third terminal) of the transistor T1 is coupled to the differential pair formed by the transistors T2 and T3. According to the above descriptions, the transistor T1 is turned on according to the clock signal CK or the inverted signal CKB to provide a current I. In other words, the current source CS1 receives the clock signal CK or the inverted signal CKB of the clock signal CK through the clock input terminal 303, and provides the current I according to the clock signal CK or the inverted signal CKB. The gate of the transistor T1 and the clock input terminal 303 can be regarded as a same node, i.e. the gate of the transistor T1 can serve as the clock input terminal 303.

A gate (corresponding to a first terminal) of the transistor T2 (corresponding to a first transistor) is equivalent to the differential data input terminal 301 (corresponding to a first terminal of the differential data input terminals), i.e. the gate of the transistor T2 can serve as the differential data input terminal 301, a source (corresponding to a second terminal) of the transistor T2 is coupled to the drain of the transistor T1 (which is equivalent to be coupled to the current source CS1), and a drain (corresponding to a third terminal) of the transistor T2 is coupled to the differential data output terminal 304 (corresponding to a first terminal of the differential data output terminals). A gate (corresponding to a first terminal) of the transistor T3 (corresponding to a second transistor) is equivalent to the differential data input terminal 302 (corresponding to a second terminal of the differential data input terminals), i.e. the gate of the transistor T3 can serve as the differential data input terminal 302, a source (corresponding to a second terminal) of the transistor T3 is coupled to the drain of the transistor T1 (which is equivalent to be coupled to the current source CS1), and a drain (corresponding to a third terminal) of the transistor T3 is coupled to the differential data output terminal 305 (corresponding to a second terminal of the differential data output terminals). In other words, the differential pair formed by the transistors T2 and T3 is coupled between the current source CS1 and the differential data output terminals 304 and 305, and is coupled to the differential signals (for example, the differential input signals Sdfin1 and Sdfin2 or the differential signals Sin1 and Sin2) through the differential data input terminals 301 and 302.

An input terminal of the inverter in41 (corresponding to a first inverter of the latch block) is coupled to the differential data output terminal 304 (corresponding to the first terminal of the differential data output terminals), and an output terminal of the inverter in41 is coupled to the differential data output terminal 305 (corresponding to the second terminal of the differential data output terminals). An input terminal of the inverter in42 (corresponding to a second inverter of the latch block) is coupled to the differential data output terminal 305, and an output terminal of the inverter in42 is coupled to the differential data output terminal 304. In other words, the latch block 310a is coupled between the differential data output terminals 304 and 305 for latching voltage levels of the differential data output terminals 304 and 305, so as to produce latched differential signals (for example, the differential signals Sin1 and Sin2 or the differential latch signals Sdl1 and Sdl2).

In the present embodiment, since charging (voltage increase) of the differential signals Sin1 and Sin2 and the differential latch signals Sdl1 and Sdl2 is implemented through the inverters (for example, in41 and in42), and the inverters do not charge the output terminals until the transistors (for example, T2 and T3) discharge (voltage decrease) the input terminals of the inverters, the level of the cross point of the differential signals Sin1 and Sin2 or the differential latch signals Sdl1 and Sdl2 is a lower level.

FIG. 3B is a circuit schematic diagram of a latch unit according to another embodiment of the invention, which can be applied but not limited to any one of the pre-drivers 110a-110d shown in FIGS. 2A-2D. Referring to FIG. 3A and FIG. 3B, a main difference between the latch unit 300a and the latch unit 300b lies in a latch block 310b and a transistor T4, where the latch block 310b is, for example, implemented by NAND gates am1 and am2. A gate of the transistor T4 receives a reset signal RST1, a source of the transistor T4 is coupled to the drain of the transistor T1, and a drain of the transistor T4 is coupled to the sources of the transistors T2 and T3, i.e. the transistor T4 is coupled between the differential pair formed by the transistors T2 and T3 and the current source CS 1.

A first input terminal of the NAND gate am1 (corresponding to a first NAND gate) is coupled to the differential data output terminal 304, a second input terminal of the NAND gate am1 receives one of a system voltage VDD and the reset signal RST1, and an output terminal of the NAND gate am1 is coupled to the differential data output terminal 305. A first input terminal of the NAND gate am2 (corresponding to a second NAND gate) is coupled to the differential data output terminal 305, a second input terminal of the NAND gate am2 receives another one of the system voltage VDD and the reset signal RST1, and an output terminal of the NAND gate am2 is coupled to the differential data output terminal 304.

Moreover, in an embodiment of the invention, the transistor T4 can be omitted, i.e. the latch unit 300b can be composed of the current source CS1, the differential pair formed by the transistors T2 and T3 and the latch block 310b, though the invention is not limited thereto.

FIG. 3C is a circuit schematic diagram of a latch unit according to still another embodiment of the invention, which can be applied but not limited to any one of the pre-drivers 110a-110d shown in FIGS. 2A-2D. Referring to FIG. 3A and FIG. 3C, a main difference between the latch unit 300a and the latch unit 300c lies in a latch block 310c and a transistor T5, where the latch block 310c is, for example, implemented by NOR gates or1 and or2. A gate of the transistor T5 receives a reset signal RST2B (which is an inverted signal of a reset signal RST2), a source of the transistor T5 is coupled to the drain of the transistor T1, and a drain of the transistor T5 is coupled to the sources of the transistors T2 and T3, i.e. the transistor T5 is coupled between the differential pair formed by the transistors T2 and T3 and the current source CS 1.

A first input terminal of the NOR gate or1 (corresponding to a first NOR gate) is coupled to the differential data output terminal 304, a second input terminal of the NOR gate or1 receives one of a ground voltage GND and the reset signal RST2, and an output terminal of the NOR gate or1 is coupled to the differential data output terminal 305. A first input terminal of the NOR gate or2 (corresponding to a second NOR gate) is coupled to the differential data output terminal 305, a second input terminal of the NOR gate or2 receives another one of the ground voltage GND and the reset signal RST2, and an output terminal of the NOR gate or2 is coupled to the differential data output terminal 304.

Moreover, in an embodiment of the invention, the transistor T5 can be omitted, i.e. the latch unit 300c can be composed of the current source CS1, the differential pair formed by the transistors T2 and T3 and the latch block 310c, though the invention is not limited thereto.

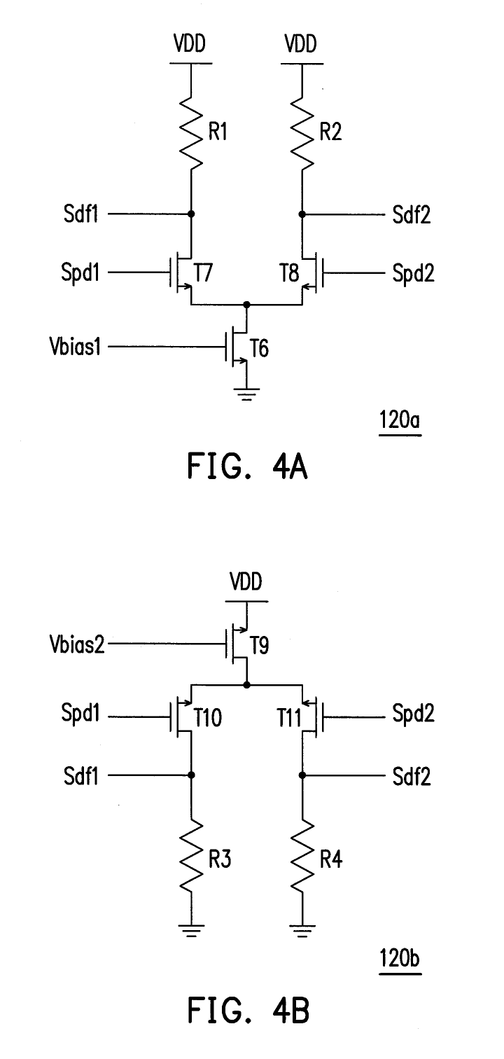

FIG. 4A is a circuit schematic diagram of a current mode driver according to an embodiment of the invention, which can be applied but not limited to the differential signal transmitter 100 of FIG. 1. Referring to FIG. 1 and FIG. 4A, in the present embodiment, the current mode driver 120a includes transistors T6-T8 and resistors R1 and R2. The transistor T6 serves as a bias current source, where a gate of the transistor T6 receives a bias Vbias1, and a source of the transistor T6 is coupled to the ground voltage. The transistors T7 and T8 serve as a differential input pair, where a gate of the transistor T7 receives the differential pre-driver output signal Spd1, a source of the transistor T7 is coupled to a drain of the transistor T6, and a drain of the transistor T7 provides the driving differential signal Sdf1 and is coupled to the system voltage VDD through the resistor R1. Similarly, a gate of the transistor T8 receives the differential pre-driver output signal Spd2, a source of the transistor T8 is coupled to the drain of the transistor T6, and a drain of the transistor T8 provides the driving differential signal Sdf2 and is coupled to the system voltage VDD through the resistor R2.

FIG. 4B is a circuit schematic diagram of a current mode driver according to another embodiment of the invention, which can be applied but not limited to the differential signal transmitter 100 of FIG. 1. Referring to FIG. 1 and FIG. 4B, in the present embodiment, the current mode driver 120b includes transistors T9-T11 and resistors R3 and R4. The transistor T9 serves as a bias current source, where a gate of the transistor T9 receives a bias Vbias2, and a source of the transistor T9 is coupled to the system voltage VDD. The transistors T10 and T11 serve as a differential input pair, where a gate of the transistor T10 receives the differential pre-driver output signal Spd1, a source of the transistor T10 is coupled to a drain of the transistor T9, and a drain of the transistor T10 provides the driving differential signal Sdf1 and is coupled to the ground voltage through the resistor R3. Similarly, a gate of the transistor T11 receives the differential pre-driver output signal Spd2, a source of the transistor T11 is coupled to the drain of the transistor T9, and a drain of the transistor T11 provides the driving differential signal Sdf2 and is coupled to the ground voltage through the resistor R4. It should be noticed that the bias current source is not limited to be implemented by the single transistor T6 or T9, but can also be implemented by other bias current sources. Similarly, the differential input pair is not limited to use the connection methods and the structures of the transistors T8 and T9 or T10 and T11, and can also use other differential input pairs. Moreover, the current mode driver 120 in the differential signal transmitter 100 of FIG. 1 is not limited to be implemented by the circuits shown in FIG. 4A and FIG. 4B, and the current mode driver of any other structure can also be used as the current mode driver 120.

The term “couple” used throughout the descriptions of the invention (including the claims) refers to a direct or indirect connection means. For example, when a first device is described to be coupled to a second device, it can be interpreted as the first device is directly connected to the second device, or the first device is indirectly connected to the second device through other devices or a certain connection means.

In summary, in the pre-driver and the differential signal transmitter using the same in the embodiments of the invention, a circuit design of the pre-driver can be simplified to reduce a chip area of the pre-driver and the differential signal transmitter using the same integrated in a chip, reduce a signal latency of the pre-driver and the differential signal transmitter using the same, reduce jitter of the differential signals, and reduce power consumption of the pre-driver and the differential signal transmitter using the same. Moreover, conversion of the differential signals can not be influenced by the manufacturing process, voltage and temperature.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A pre-driver, comprising:
a latch circuit, comprising:
one or more latch units, coupled in series between a pair of differential input terminals and a pair of differential latch terminals, receiving a pair of differential input signals through the pair of differential input terminals, and latching the pair of differential input signals according to a clock signal to provide a pair of differential latch signals through the pair of differential latch terminals;
one or more first inverters, coupled in series between a first terminal of the pair of differential latch terminals and a first terminal of a pair of differential output terminals; and
one or more second inverters, coupled in series between a second terminal of the pair of differential latch terminals and a second terminal of the pair of differential output terminals; and
a driver buffer, having a pair of buffer input terminals coupled to the pair of differential output terminals of the latch circuit to receive a pair of differential output signals, and accordingly providing a pair of differential pre-driver output signals through a pair of buffer output terminals according to the pair of differential output signals.

2. The pre-driver as claimed in claim 1, wherein the one or more first inverters and the one or more second inverters are used to adjust a level of a cross point of the pair of differential latch signals to produce the pair of differential output signals.

3. The pre-driver as claimed in claim 1, wherein
each of the latch units has a clock input terminal, a pair of differential data input terminals and a pair of differential data output terminals,
the pair of differential data input terminals of a first one of the one or more latch units serve as the pair of differential input terminals,
the pair of differential data input terminals of each of the one or more latch units besides the first latch unit are coupled to the differential data output terminals of a previous latch unit,
the pair of differential data output terminals of a last one of the one or more latch units serve as the pair of differential latch terminals, and
the clock input terminal of each of the one or more latch units receives one of the clock signal and an inverted signal of the clock signal, latches a pair of differential signals received by the pair of differential data input terminals according to the clock signal or the inverted signal, and outputs the latched pair of differential signals through the pair of differential data output terminals.

4. The pre-driver as claimed in claim 3, wherein each of the one or more latch units comprises:
a current source, receiving the clock signal or the inverted signal of the clock signal through the clock input terminal, and providing a current according to the clock signal or the inverted signal;
a differential pair, coupled between the current source and the pair of differential data output terminals, and coupled to the pair of differential signals through the pair of differential data input terminals; and
a latch block, coupled between a first terminal and a second terminal of the pair of differential data output terminals, and latching voltage levels of the pair of differential data output terminals to produce the latched pair of differential signals.

5. The pre-driver as claimed in claim 4, wherein the current source comprises:
a transistor, having a first terminal serving as the clock input terminal, a second terminal coupled to a reference voltage, and a third terminal coupled to the differential pair.

6. The pre-driver as claimed in claim 4, wherein the differential pair comprises:
a first transistor, having a first terminal serving as a first terminal of the pair of differential data input terminals, a second terminal coupled to the current source, and a third terminal coupled to the first terminal of the pair of differential data output terminals; and
a second transistor, having a first terminal serving as a second terminal of the pair of differential data input terminals, a second terminal coupled to the current source, and a third terminal coupled to the second terminal of the pair of differential data output terminals.

7. The pre-driver as claimed in claim 4, wherein the latch block comprises:
a first inverter, having an input terminal coupled to the first terminal of the pair of differential data output terminals, and an output terminal coupled to the second terminal of the pair of differential data output terminals; and
a second inverter, having an input terminal coupled to the second terminal of the pair of differential data output terminals, and an output terminal coupled to the first terminal of the pair of differential data output terminals.

8. The pre-driver as claimed in claim 4, wherein the latch block comprises:
a first NAND gate, having a first input terminal coupled to the first terminal of the pair of differential data output terminals, a second input terminal receiving one of a system voltage and a reset signal, and an output terminal coupled to the second terminal of the pair of differential data output terminals; and
a second NAND gate, having a first input terminal coupled to the second terminal of the pair of differential data output terminals, a second input terminal receiving another one of the system voltage and the reset signal, and an output terminal coupled to the first terminal of the pair of differential data output terminals.

9. The pre-driver as claimed in claim 4, wherein the first latch circuit comprises:
a first NOR gate, having a first input terminal coupled to the first terminal of the pair of differential data output terminals, a second input terminal receiving one of a ground voltage and a reset signal, and an output terminal coupled to the second terminal of the pair of differential data output terminals; and
a second NOR gate, having a first input terminal coupled to the second terminal of the pair of differential data output terminals, a second input terminal receiving another one of the ground voltage and the reset signal, and an output terminal coupled to the first terminal of the pair of differential data output terminals.

10. The pre-driver as claimed in claim 4, further comprising an inverter configured to invert a data signal, wherein the inverted data signal and the data signal serve as the pair of differential input signals.

11. A differential signal transmitter, comprising:
the pre-driver as claimed in claim 1; and
a current mode driver, coupled to the pre-driver.
